(19) United States
(12) Patent Application Publication
(10) Pub. No.: US 2026/0047490 A1
(43) Pub. Date: Feb. 12, 2026

(54) HIGH BANDWIDTH MEMORY AND METHOD FOR MANUFACTURING THE SAME

(71) Applicant: SAMSUNG ELECTRONICS CO., LTD., SUWON-SI (KR)

(72) Inventors: BUM-SOO KIM, Suwon-si (KR); HYUNSU HWANG, Suwon-si (KR); JUMYONG PARK, Suwon-si (KR); DONGJOON OH, Suwon-si (KR); SANGHOO CHO, Suwon-si (KR)

(21) Appl. No.: 19/070,705

(22) Filed: Mar. 5, 2025

(30) Foreign Application Priority Data
Aug. 6, 2024 (KR) 10-2024-0104494

(51) Int. Cl. H01L 25/18; H01L 21/56; H01L 23/00; H01L 23/29; H01L 23/31; H10B 80/00; H10D 80/30

(52) U.S. Cl. CPC H01L 25/18; H01L 21/566; H01L 23/296; H01L 23/3135; H01L 24/27; H01L 24/32; H01L 24/33; H01L 24/83; H10B 80/00; H10D 80/30; H01L 24/16; H01L 24/29; H01L 2224/16148; H01L 2224/27831; H01L 2224/29386; H01L 2224/32059; H01L 2224/32145; H01L 2224/3303; H01L 2224/8391; H01L 2924/1431; H01L 2924/1436

(57) ABSTRACT

In an embodiment of the present inventive concept, a high bandwidth memory includes a base die, and a semiconductor stack disposed on the base die, the semiconductor stack comprising a plurality of underfill members and a plurality of memory dies that are alternately stacked. Each of the plurality of underfill members includes first sides, each of the plurality of memory dies includes second sides, and each of the first sides is recessed from a corresponding second side.

### CROSS-REFERENCE TO RELATED APPLICATION

This application claims priority under 35 U.S.C. § 119 to Korean Patent Application No. 10-2024-0104494, filed in the Korean Intellectual Property Office on Aug. 6, 2024, the entire contents of which are herein incorporated by reference.

### TECHNICAL FIELD

The present disclosure relates to a high bandwidth memory and a method for manufacturing the same.

### DISCUSSION OF THE RELATED ART

As the demand for smaller, and lighter electronic devices grows, the semiconductor industry is focused on miniaturizing, reducing the weight, and thinning semiconductor packages while simultaneously enhancing the speed, functionality, and capacity. Accordingly, there is an increasing need for packaging technologies, such as high bandwidth memory (HBM), that can store more data and transmit data at faster speeds by stacking multiple individual memory dies.

High bandwidth memory (HBM) is manufactured by a combination of memory dies. One of the factors to consider during the combining process is the high density of input/output (I/O) connections between the memory dies. If the density of I/O is increased so that the density of electrical signal connections becomes similar to the density of copper wiring in the semiconductor front-end process, combining memory dies in the semiconductor back-end process may produce results similar to those of a single semiconductor chip made through the semiconductor front-end process.

To manufacture such high bandwidth memories HBM, the memory dies are bonded by performing thermal compression TC bonding on micro bumps and underfill members positioned between the memory dies. However, after performing thermal compression TC bonding, the underfill member may overflow, forming fillets that expose the underfill member outside the sides of the memory dies. These fillets form irregular interfaces with the molding material covering the memory dies, and the irregular interfaces caused by the fillets may cause cracks to form, making the high bandwidth memory HBM structurally unstable.

### SUMMARY

The present disclosure is to provide a high bandwidth memory capable of removing the fillet of the underfill member by performing plasma etching.

In an embodiment of the present inventive concept, a high bandwidth memory includes a base die, and a semiconductor stack disposed on the base die, the semiconductor stack comprising a plurality of underfill members and a plurality of memory dies that are alternately stacked. Each of the plurality of underfill members includes first sides, each of the plurality of memory dies includes second sides, and each of the first sides is recessed from a corresponding second side.

In an embodiment of the present inventive concept, a high bandwidth memory includes a buffer die, a semiconductor stack disposed on the buffer die, and a molding material covering the semiconductor stack disposed on the buffer die. The semiconductor stack comprises a plurality of core dies stacked in vertical direction, and a plurality of interconnection structures, each interconnection structure being disposed between the buffer die and a core die adjacent to the buffer die, or between neighboring core dies. Each of the plurality of interconnection structures includes a plurality of connection members, and an underfill member disposed around the plurality of connection members. The underfill member between neighboring core dies includes first sides, each of the plurality of core dies comprises second sides, and each of the first sides of the underfill member is recessed from a corresponding second side.

A method for manufacturing a high bandwidth memory according to an embodiment of the present inventive concept includes stacking a plurality of underfill members and a plurality of memory dies alternately on a base die, performing plasma etching such that each of first sides of the plurality of underfill members is recessed from a corresponding second side of the plurality of memory dies, and molding the plurality of underfill members and the plurality of memory dies with a molding material on the base die.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view illustrating a high bandwidth memory (HBM) according to an embodiment of the present inventive concept.

FIG. 2 is a plan view illustrating a top surface of the high bandwidth memory HBM according to an embodiment of the present inventive concept illustrated in FIG. 1.

FIGS. 3, 4, 5, 6, 7, 8, and 9 are cross-sectional views illustrating a method of manufacturing a high bandwidth memory (HBM) according to an embodiment of the present inventive concept.

### DETAILED DESCRIPTION OF THE EMBODIMENTS

Hereinafter, embodiments of the present inventive concept will be described in detail with reference to the accompanying drawings so that those skilled in the art may easily implement the present disclosure. The present disclosure may be implemented in a number of different forms and is not necessarily limited to the embodiments described herein.

The drawings and description are to be regarded as illustrative in nature and not necessarily restrictive. In the specification and figures, like reference numerals may denote like elements or features, and thus, repetitive descriptions may be omitted.

Hereinafter, example embodiments of the present inventive concept will be described in detail with reference to the attached drawings. However, the spirit and scope of the present inventive concept should not be limited to the example embodiments set forth herein because the present inventive concept may be embodied in various different forms. In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Throughout this specification, when a part is “connected” to another element, it may include not only being “directly connected” but also being “indirectly connected” with other members in between. In addition, when a part “includes” or “comprises” a component throughout the specification, this means other components may be further included, rather than excluding other components unless otherwise stated.

Spatially relative terms, such as “beneath,” “below,” “lower,” “on,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

In addition, throughout the specification, when it comes to “on a plane,” it means when the target part is viewed from above, and when it comes to “cross-section,” it means when the cross-section of the target part is vertically cut from the side.

Example embodiments of the present inventive concept relate to a semiconductor package design and its manufacturing method aimed at improving the structural stability of high bandwidth memory (HBM) devices. The design minimizes the formation of fillets and facilitates the efficient removal of fillets that may form between the buffer die and the semiconductor die during the manufacturing process.

According to this approach, the structural integrity of the high bandwidth memory (HBM) may be enhanced by reducing the risk of undesirable fillet formation. Additionally, it increases the efficiency of fillet removal through the use of plasma etching process.

Unlike conventional mechanical cutting methods, which were previously used to remove the fillets but often proven inefficient and prone to inconsistencies, the plasma etching process provides a more effective solution. This method allows for the simultaneous removal of fillets that form on semiconductor stacks, such as those on a wafer, ensuring a uniform and precise outcome.

More specifically, it may be challenging to remove the fillet between the buffer die, especially in the lowermost portion, using mechanical cutting equipment due to the size disparity between the buffer die and the memory die. However, this fillet may be efficiently removed through a plasma etching process, which overcomes the limitations of mechanical cutting.

Furthermore, the present inventive concept allows for the simultaneous removal fillets formed in the semiconductor stacks on the wafer. The present inventive concept reduces the time required for fillet removal and enhances productivity in the production of high bandwidth memory (HBM).

Hereinafter, a high bandwidth memory HBM 100 according to an embodiment of the present inventive concept will be described with reference to the drawings.

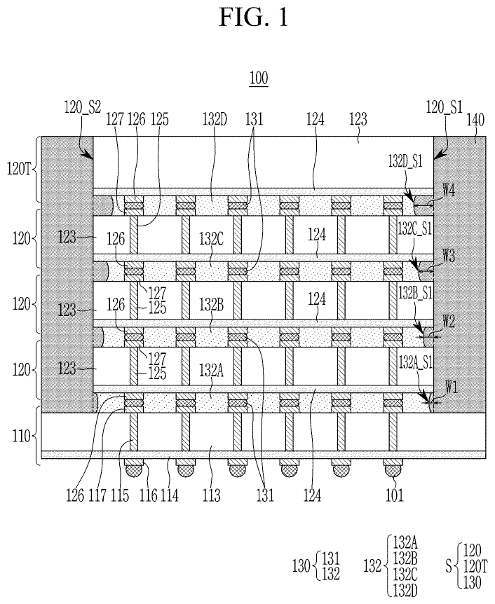

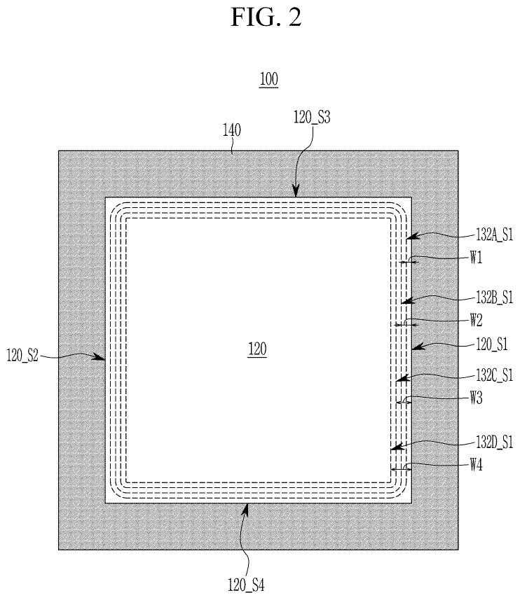

FIG. 1 is a cross-sectional view illustrating a high bandwidth memory HBM 100 according to an embodiment of the present inventive concept. FIG. 2 is a plan view illustrating a top surface of the high bandwidth memory HBM 100 according to an embodiment of FIG. 1.

Referring to FIG. 1, a high bandwidth memory (HBM) 100 may include a buffer die (base logic die; base die) 110, a semiconductor stack S including memory dies 120 and 120T and interconnection structures 130, and a molding material 140. The interconnection structures 130 may include first connection members 131 and underfill members 132. The underfill members 132 may include first underfill member 132A, second underfill member 132B, third underfill member 132C, and fourth underfill member 132D. The high bandwidth memory (HBM) 100 may be a high-performance, three-dimensional (3D) stacked dynamic random-access memory (DRAM). The high bandwidth memory (HBM) 100 may have multiple memory channels through a semiconductor stack S, which is manufactured by vertically stacking memory dies 120 and 120T. The high bandwidth memory (HBM) may simultaneously implement shorter latency and higher bandwidth than conventional DRAM products, and may reduce the total area occupied by individual DRAMs on the substrate, which is advantageous for high bandwidth compared to the area, and has the advantage of reducing power consumption.

The buffer die 110 may be disposed at the bottom of the high bandwidth memory (HBM) 100, and may be disposed between the semiconductor stack S and the external device. When data is exchanged between devices with different processing speeds, processing units, and usage times of data, data loss may occur due to differences in processing speeds, processing units, and usage times between devices. The buffer die 110 disposed between the semiconductor stack S and the external device may reduce the data loss. When exchanging data between the semiconductor stack S and the external device, information may be temporarily stored in the buffer die 110. When transmitting data to the semiconductor stack S or receiving data from the semiconductor stack S, the buffer die 110 may sequentially pass the data after arranging the data.

The buffer die 110 may include a buffer die base 113, a first front side structure 114 disposed under the buffer die base 113, first through silicon vias 115 disposed within the buffer die base 113, first connection pads 116 disposed under the first front side structure 114, and first bonding pads 117 disposed on the buffer die base 113.

The buffer die base 113 may include an active side (front side) and a back side, which is disposed opposite to the active side. The active side of the buffer die may be disposed such that its active side faces an external device. The back side of the buffer die base 113 may be disposed such that its back side faces the memory dies 120 and 120T. The buffer die base 113 may be a die formed from a wafer 110W. In an embodiment of the present inventive concept, the buffer die base 113 may include silicon or other semiconductor material.

The first front side structure 114 may be positioned on the active side of the buffer die base 113. The first front side structure 114 may include an active layer and a wiring layer. The active layer may be disposed on the active side of the buffer die base 113. The active layer may include an integrated circuit structure having integrated circuit regions. In an embodiment of the present inventive concept, the integrated circuit structure may include at least one of an active devices and a passive device. In an embodiment of the present inventive concept, the integrated circuit structure may include a gate structure, a source region, and a drain region. In an embodiment of the present inventive concept, the integrated circuit structure may include at least one of a transistor, a diode, a capacitor, an inductor, and a resistor. The wiring layer may be disposed on the active layer. The wiring layer may include signal wiring lines, power wiring lines, contact plugs, and inter metal dielectric (IMD).

The first through silicon vias 115 may be disposed within the buffer die base 113. For example, the buffer die base 113 may surround the first through silicon vias 115. Each of the first through silicon vias 115 may penetrate the buffer die base 113 and be positioned between the active layer or wiring layer of the first front side structure 114 and each of the first bonding pads 117. For example, the first through silicon vias 115 may vertically extend and may be in contact with the active layer or wiring layer of the first front side structure 114 and the first bonding pads 117. Each of the first through silicon vias 115 may electrically connect an active layer or a wiring layer of the first front side structure 114 to a respective first bonding pads 117. In an embodiment of the present inventive concept, the first through silicon vias 115 may include at least one of tungsten, aluminum, copper, and alloys thereof.

Each of the first connection pads 116 may be positioned between the wiring layer of the first front side structure 114 and each of external connection members 101. For example, the first connection pads 116 may be disposed on a lower surface of the first front side structure 114. Each of the first connection pads 116 may electrically connect the wiring layer of the first front side structure 114 to each of the external connection members 101. In an embodiment of the present inventive concept, the first connection pads 116 may include at least one of copper, aluminum, tungsten, nickel, gold, tin, titanium, and alloys thereof.

The first bonding pads 117 may be disposed on the back side of the buffer die base 113. Each of the first bonding pads 117 may be positioned between each of the first through silicon vias 115 and each of the first connection members 131. Each of the first bonding pads 117 may electrically connect each of the first through silicon vias 115 to each of the connection members 131. In an embodiment of the present inventive concept, the first bonding pads 117 may include at least one of copper, aluminum, tungsten, nickel, gold, tin, titanium, and alloys thereof.

Each of the external connection members 101 may be disposed between each of the first connection pads 116 and an external device. Each of the external connection members 101 may electrically connect each of the first connection pads 116 to an external device. In an embodiment of the present inventive concept, the external connection members 101 may include micro bumps or solder balls. In an embodiment of the present inventive concept, the external connection members 101 may include at least one of tin, silver, lead, nickel, copper, and alloys thereof.

A semiconductor stack S may be disposed on a buffer die 110. The semiconductor stack S may include memory dies (core dies) 120 and interconnection structures 130. Memory dies 120 and 120T may be stacked vertically and sequentially on the buffer die 110. Each of the interconnection structures 130 may be disposed between a buffer die 110 and a memory die 120, or between neighboring memory dies 120 and 120T among the memory dies 120 and 120T. A high bandwidth memory (HBM) 100 according to the present inventive concept includes a semiconductor stack S in which four memory dies 120 and 120T and four interconnection structures 130 are stacked, but is not necessarily limited thereto, and may include a semiconductor stack S in which various numbers of memory dies 120 and 120T and interconnection structures 130 are stacked. For example, a high bandwidth memory (HBM) 100 may include a semiconductor stack S of eight, twelve, sixteen, or twenty-four memory dies 120 and 120T and interconnection structures 130.

A memory die 120 may include a memory die base 123, a second front side structure 124 disposed under the memory die base 123, second through silicon vias 125 disposed within the memory die base 123, second connection pads 126 disposed under the second front side structure 124, and second bonding pads 127 disposed on the memory die base 123. A memory die 120T positioned at the top of a semiconductor stack S may include a memory die base 123, a second front side structure 124 disposed under the memory die base 123, and second connection pads 126 disposed under the second front side structure 124.

The memory die base 123 may include an active side (front side) and a back side disposed opposite to the active side. The memory die base 123 may be disposed such that its active side faces the buffer die 110. The memory die base 123 may be a die formed from a wafer 110W. In an embodiment of the present inventive concept, the memory die base 123 may include silicon or other semiconductor material.

The second front side structure 124 may be disposed on an active side of the memory die base 123. The second front side structure 124 may include an active layer and a wiring layer. The active layer may be disposed on the active side of the memory die base 123. The active layer may include an integrated circuit structure having integrated circuit regions. In an embodiment of the present inventive concept, the integrated circuit structure may include at least one of an active device and a passive device. In an embodiment of the present inventive concept, the integrated circuit structure may include a gate structure, a source region, and a drain region. In an embodiment of the present inventive concept, the integrated circuit structure may include at least one of a transistor, a diode, a capacitor, an inductor, and a resistor. The wiring layer may be disposed on the active layer. The wiring layer may include signal wiring lines, power wiring lines, contact plugs, and an inter metal dielectric IMD.

The second through silicon vias 125 may be positioned within the memory die base 123. The memory die base 123 may surround the second through silicon vias 125. Each of the second through silicon vias 125 may penetrate the memory die base 123 and be positioned between the active layer or wiring layer of the second front side structure 124 and each of the second bonding pads 127. For example, the second through silicon vias 125 may vertically extend and may be in contact with the active layer or wiring layer of the second front side structure 124 and the second bonding pads 127. Each of the second through silicon vias 125 may electrically connect an active layer or a wiring layer of the second front side structure 124 to a respective one of the second bonding pads 127. In an embodiment of the present inventive concept, the second through silicon vias 125 may include at least one of tungsten, aluminum, copper, and alloys thereof.

Each of the second connection pads 126 may be positioned between the wiring layer of the second front side structure 124 and each of the connection members 131. Each of the second connection pads 126 may electrically connect the wiring layer of the second front side structure 124 to each of the connection members 131. In an embodiment of the present inventive concept, the second connection pads 126 may include at least one of copper, aluminum, tungsten, nickel, gold, tin, titanium, and alloys thereof.

The second bonding pads 127 may be disposed on the back side of the memory die base 123. Each of the second bonding pads 127 may be disposed between each of the second through silicon vias 125 and each of the connection members 131. Each of the second bonding pads 127 may be electrically connected to each of the second through silicon via 125 to each of the connection members 131. In an embodiment of the present inventive concept, the second bonding pads 127 may include at least one of copper, aluminum, tungsten, nickel, gold, tin, titanium, and alloys thereof.

Interconnection structures 130 may be stacked alternately along a vertical direction with memory dies 120 and 120T within a semiconductor stack S. For example, the first connection members 131 and the underfill members 132 may be stacked on the buffer die 110. Each of the interconnection structures 130 may be disposed between a buffer die 110 and a memory die 120 adjacent to the buffer die 110, or between neighboring memory dies 120 and 120T. Each of the interconnection structures 130 may include connection members 131 and underfill members 132 around the interconnection members 131.

Each of the connection members 131 may be disposed between each of the first bonding pads 117 of the buffer die 110 and each of the second connection pads 126 of the memory die 120 adjacent to the buffer die 110, or between each of the second bonding pads 127 of the memory die 120 and each of the second connection pads 126 of the memory die 120 and 120T neighboring each other. Each of the connection members 131 may electrically connect each of the second connection pads 126 of a memory die 120 adjacent to the buffer die 110 to each of the first bonding pads 117 of the buffer die 110, or each of the second connection pads 126 of the memory die 120 and 120T to each of the second bonding pads 127 of the neighboring memory die 120. For example, the connection members 131 may be disposed between the buffer die 110 and the memory dies 120, and may be disposed between the memory dies 120 and 120T. In an embodiment of the present inventive concept, the connection members 131 may include micro bumps. In an embodiment of the present inventive concept, the connection members 131 may include at least one of tin, silver, lead, nickel, copper, and alloys thereof.

Each of the underfill members 132 may be disposed between a buffer die 110 and a memory die 120 adjacent to the buffer die 110, or between the neighboring memory dies 120 and 120T among the memory dies 120 and 120T. An underfill member 132 disposed between a buffer die 110 and memory dies 120 adjacent to the buffer die 110 may surround and insulate the first bonding pads 117, the connection members 131, and the second connection pads 126. The underfill member 132 disposed between the neighboring memory dies 120 and 120T may surround and insulate the second bonding pads 127, the connection members 131, and the second connection pads 126. In an embodiment of the present inventive concept, the underfill members 132 may include a non-conductive film (NCF).

The underfill members 132 may include at least one of a thermosetting resin, a hardener, a catalyst, a flux, a thermoplastic resin, and an inorganic filler.

The thermosetting resin may be selected from materials having suitable thermal or mechanical properties as an underfill film. In an embodiment of the present inventive concept, the thermosetting resin may comprise an epoxy resin. In an embodiment of the present inventive concept, the epoxy resin may include at least one of a bisphenol-type epoxy resin and a novolac-type epoxy resin.

A hardener may be added to a thermosetting resin to harden the thermosetting resin. The hardener may be added to control the degree of curing of the thermosetting resin. Mechanical properties of the underfill member 132 may be adjusted by adding the hardener to the thermosetting resin. In an embodiment of the present inventive concept, the hardener may include at least one of an amine-based compound, an acid anhydride-based compound, an amide-based compound, an imidazole-based compound, and a phenol-based compound.

The catalyst may be added to the thermosetting resin to control the curing rate of the thermosetting resin. The curing rate of the thermosetting resin may be controlled according to the content of the catalyst or may be controlled using a catalyst that slows the curing rate. In an embodiment of the present inventive concept, the catalyst may include at least one of a phosphorus-based compound, a boron-based compound, a phosphorus-boron-based compound, and an imidazole-based compound.

The flux may improve wetting of the connection member 131 with respect to the first bonding pad 117 or the second bonding pad 127. In an embodiment of the present inventive concept, the flux may include at least one of carboxylic acid, phenol, and amine.

The thermoplastic resin may increase the fluidity of the underfill member 132 at a temperature (reflow temperature) at which thermal compression (TC) bonding is performed, so that the connection member 131 may form a strong bond with the first bonding pad 117 or the second bonding pad 127. The thermoplastic resin may reduce thermal stress and mechanical stress between the buffer die 110 and the memory die 120, or between the neighboring memory dies 120 and 120T among the memory dies 120 and 120T. In an embodiment of the present inventive concept, the thermoplastic resin may include at least one of a polyimide-based resin, a polyether imide-based resin, a polyester imide-based resin, a polyamide-based resin, a polyether sulfone-based resin, a polyether ketone-based resin, a polyolefin-based resin, a polyvinyl chloride-based resin, a phenoxy-based resin, a butadiene rubber, a styrene-butadiene rubber, a modified butadiene rubber, a reactive butadiene acrylonitrile copolymer rubber, and an acrylate-based resin.

The inorganic filler may be added as a filler in the underfill member 132 and may suppress the flow of the underfill member 132 to increase the bonding reliability of the connection member 131 to the first bonding pad 117 or the second bonding pad 127. In an embodiment of the present inventive concept, the first inorganic filler may comprise silica.

Referring to FIGS. 1 and 2, each side of the underfill members 132 may be recessed from the sides of the memory dies 120. In FIG. 2, each side of the underfill members 132 is illustrated with a dotted line. In reality, each side of the underfill members 132 may extend with an irregular profile, but in FIG. 2, the profile of the approximate average value of each side of the underfill members 132 is assumed and is depicted as extending in a straight line.

The second, third, and fourth underfill members 132B, 132C, and 132D disposed between the neighboring memory dies 120 and 120T among the memory dies 120 and 120T may include sides (first sides) that contact the molding material 140. Each of the sides of the second, third, and fourth underfill members 132B, 132C, and 132D may be recessed from a corresponding side (second sides) among the sides of the memory die 120 and 120T. The underfill member 132B may include one side 132B_S1 that contacts the molding material 140, and the one side 132B_S1 of the underfill member 132B may be at a position recessed by a second interval W2 with respect to a corresponding one side 120_S1 of the memory die 120. For example, at a distance of the second interval W2 away from the side 120_S1, the side 132B_S1 of the second underfill member 132B may be recessed, curving inward. The underfill member 132C may include a side 132C_S1 contacting the molding material 140, and one side 132C_S1 of the third underfill member 132C may be at a position recessed by a third interval W3 with respect to a corresponding side 120_S1 of the memory die 120. For example, at a distance of the third interval W3 away from the side 120_S1, the side 132C_S1 of the third underfill member 132C may be recessed, curving inward. The underfill member 132D may include a side 132D_S1 in contact with the molding material 140, and one side 132D_S1 of the fourth underfill member 132D may be at a position recessed by the fourth interval W4 with respect to the corresponding side 120_S1 of the memory die 120. For example, at a distance of the fourth interval W4 away from the side 120_S1, the side 132D_S1 of the fourth underfill member 132D may be recessed, curving inward.

The first underfill member 132A disposed between the buffer die 110 and the memory die 120 adjacent to the buffer die 110 may include sides (third sides) in contact with the molding material 140. Each of the sides of the first underfill member 132A may be recessed from a corresponding side among the sides (second sides) of the memory die 120. For example, the first underfill member 132A may include one side 132A_S1 in contact with the molding material 140, and one side 132A_S1 of the underfill member 132A may be at a position recessed by the first interval W1 with respect to the corresponding side 120_S1 of the memory die 120. In an embodiment of the present inventive concept, each of the sides of the first underfill member 132A might not be recessed from a corresponding side among the sides (second sides) of the memory die 120.

As the underfill member 132 is disposed farther away from the buffer die 110, one side 132A_S1, 132B_S1, 132C_S1, and 132D_S1 among the sides of the underfill member 132 may be recessed farther away from the corresponding side 120_S1 and 120_S2 among the sides of the memory die 120. For example, the fourth interval W4 which is the recess interval of the fourth underfill member 132D may be greater than the third interval W3 which is the recess interval of the third underfill member 132C, the third interval W3 which is the recess interval of the third underfill member 132C may be greater than the second interval W2 which is the recess interval of the second underfill member 132B, and the second interval W2 which is the recess interval of the second underfill member 132B may be greater than the first interval W1 which is the recess interval of the first underfill member 132A. In an embodiment of the present inventive concept, each of the sides of the first underfill member 132A may have a concave profile.

The molding material 140 may be disposed on the buffer die 110 and may cover the semiconductor stack S. For example, the molding material 140 may cover side surfaces of the memory dies 120 and 120T, and the interconnection structures 130. The molding material 140 may serve to protect and insulate the semiconductor stack S. In an embodiment of the present inventive concept, the molding material 140 may be an epoxy molding compound (EMC). In an embodiment of the present inventive concept, the molding material 140 may include at least one of a thermosetting resin, a hardener, a flame retardant, a catalyst, a release agent, a modifier, a colorant, and an inorganic filler. In an embodiment of the present inventive concept, the inorganic filler of the molding material 140 may include silica.

The molding material 140 may be disposed between the buffer die 110 and the memory die 120 adjacent to the buffer die 110, and between the neighboring memory dies 120 and 120T among the memory dies 120 and 120T. The molding material 140 may cover a predetermined interval W1, W2, W3, and W4 from one side 132A_S1, 132B_S1, 132C_S1, and 132D_S1 among the sides of the underfill member 132 to a corresponding side 120_S1 and 120_S2 among the sides of the memory die 120. For example, the molding material 140 may cover the range of the first interval W1, which is a predetermined distance from one side 132A_S1 among the sides of the first underfill member 132A to the corresponding one side 120_S1 among the sides of the memory die 120. The molding material 140 may cover a range of a second interval W2, which is a predetermined distance from one side 132B_S1 among the sides of the second underfill member 132B to the corresponding one side 120_S1 among the sides of the memory die 120. The molding material 140 may cover a range of a third interval W3, which is a predetermined distance from one side 132C_S1 among the sides of the third underfill member 132C to the corresponding one side 120_S1 among the sides of the memory die 120. The molding material 140 may cover a range of a fourth interval W4, which is a predetermined distance from one side 132D_S1 among the sides of the fourth underfill member 132D to the corresponding one side 120_S1 among the sides of the memory die 120.

The predetermined distance covered by the molding material 140 may increase as it gets farther away from the buffer die 110. For example, the fourth interval W4 covered by the molding material 140 may be greater than the third interval W3 covered by the molding material 140, the third interval W3 covered by the molding material 140 may be greater than the second interval W2 covered by the molding material 140, and the second interval W2 covered by the molding material 140 may be greater than the first interval W1 covered by the molding material 140.

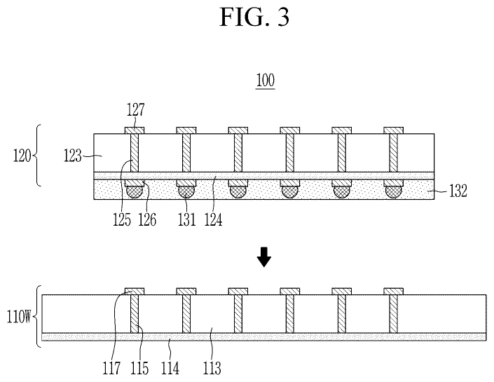

FIGS. 3 to 9 are cross-sectional views illustrating a method of manufacturing a high bandwidth memory (HBM) 100 according to an embodiment of the present inventive concept.

FIG. 3 is a cross-sectional view illustrating a step of aligning the memory die 120 on a wafer 110W including the buffer dies 110.

Referring to FIG. 3, the memory die 120 may be aligned on a wafer 110W including the buffer dies 110. The underfill member 132 may be attached to the lower surface of the memory die 120, and the connection members 131 and the second connection pads 126 may be surrounded by the underfill member 132.

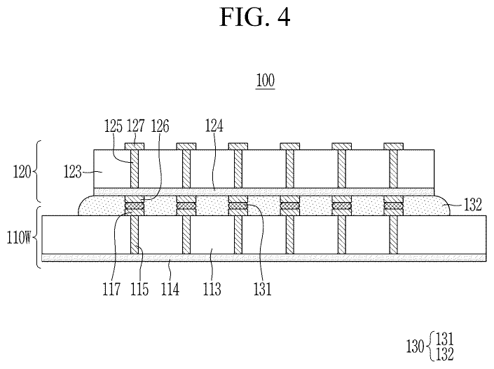

FIG. 4 is a cross-sectional view illustrating a step of bonding the memory die 120 onto the wafer 110W.

Referring to FIG. 4, a memory die 120 may be bonded onto a wafer 110W. The memory die 120 may be bonded onto the wafer 110W by a thermal compression (TC) process. By a thermal compression (TC) process, each of the connection members 131 may be bonded to each of the first bonding pads 117.

The underfill member 132 may be disposed between the wafer 110W and the memory die 120, may be attached to the wafer 110W and the memory die 120, and may protect and insulate the first bonding pads 117, the connection members 131, and the second bonding pads 127. The underfill member 132 may be in a gel state before performing the thermal compression (TC) process, and heat may be applied during the thermal compression (TC) process to change the underfill member 132 from a gel state to a liquid state, until the underfill member 132 becomes a cured state. For example, after the thermal compression (TC) is complete, the underfill member 132 may solidify into a stable form. During the thermal compression (TC) process, the liquid underfill member 132 before it becomes the cured state may flow out from between the wafer 110W and the memory die 120 and 120T. Then, the underfill member 132 flowing out may become the cured state and become a fillet after the thermal compression (TC) process is completed. For example, the cured underfill member 132 may form the fillet, which is a rounded edge that forms along edges, where the memory die 120 and 120T meets the wafer 110W.

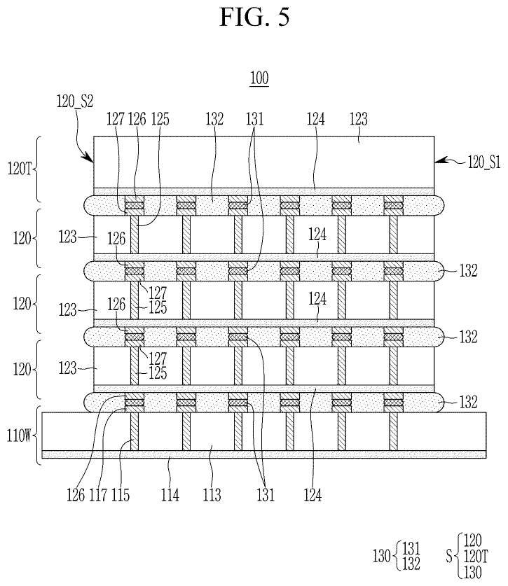

FIG. 5 is a cross-sectional view illustrating a step of stacking the memory dies 120.

Referring to FIG. 5, by repeating the alignment of the memory dies 120 and the thermal compression TC process, the memory dies 120 and the underfill members 132 may be stacked so that the memory dies 120 and the underfill members 132 alternate with each other. As described above in FIG. 4, during the thermal compression TC process, the liquid underfill member 132 may flow out from between the memory dies 120 to the outside. Once the thermal compression TC process is complete, the flowing underfill member 132 may cure and solidify, forming a fillet around the edges.

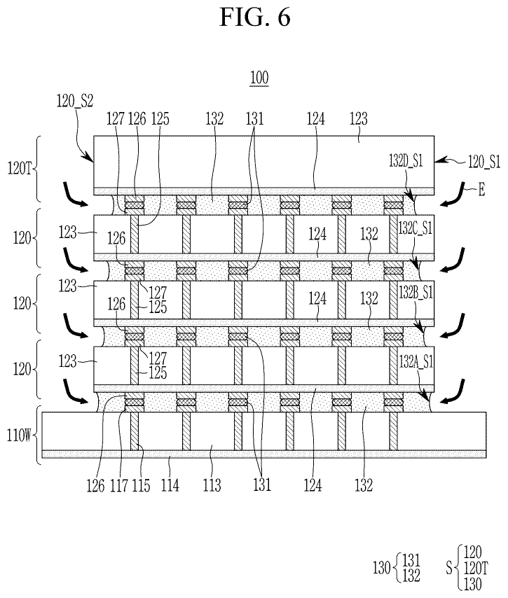

FIG. 6 is a cross-sectional view illustrating a step of performing plasma etching E to remove fillets of the underfill member 132.

Referring to FIG. 6, plasma etching E may be performed to remove fillets of the underfill member 132. After performing plasma etching E, each of the respective sides 132A_S1, 132B_S1, 132C_S1, and 132D_S1 of the underfill members 132 may be recessed from a corresponding one side 120_S1 among the sides of the memory die 120. In an embodiment of the present inventive concept, the plasma etching E may include oxygen plasma etching. In an embodiment of the present inventive concept, the plasma etching E may include isotropic plasma etching. In an embodiment of the present inventive concept, plasma etching E may be performed in a pressure range from about 0.2 to about 1 torr. In an embodiment of the present inventive concept, the plasma etching E may be performed in a temperature ranging from about 70° C. to about 250° C. At a temperature of about 70° C. or less, the etching rate of the cured underfill member 132 may be slowed, and at a temperature of about 250° C. or higher, the components of the wafer 110W and the memory die 120 may react with the etching gas to generate an outgas, and the circuit may be damaged. In an embodiment of the present inventive concept, more preferably, the plasma etching E may be performed in a temperature ranging from about 150° C. to about 200° C.

Since the etching amount at the top of the plasma etching E is larger than the etching amount at the bottom, the sides 132B_S1, 132C_S1, and 132D_S1 of the underfill member 132 located far from the buffer die 110 may be etched more than the sides 132A_S1, 132B_S1, and 132C_S1 of the underfill member 132 located close to the buffer die 110. Therefore, as the underfill member 132 is farther away from the buffer die 110, one side 132B_S1, 132C_S1, and 132D_S1 among the sides of the underfill member 132 may be recessed larger from the corresponding side 120_S1 of the sides of the memory die 120.

Since the thermosetting resin, the thermoplastic resin, and the flux of the underfill member 132 may be composed of the organic compound of CxHyOz, and the hardener of the underfill member 132 may be composed of the organic compound of CxHyNzOa, the thermosetting resin, the thermoplastic resin, and the flux of the underfill member 132 may be removed by generating by-products such as CO, CO2, NxO, and H2O by oxygen plasma etching. By-products such as CO, CO2, NxO, and H2O may be removed by pumping.

On the other hand, the inorganic filler of the underfill member 132 is made of silica, and silica might not be removed by oxygen plasma etching and may remain as an etching by-product. In an embodiment of the present inventive concept, silica not removed by oxygen plasma etching may be removed by flushing before molding is performed. In an embodiment of the present inventive concept, a separate process for removing silica not removed by oxygen plasma etching might not be performed. Since silica that has not been removed has the same configuration as silica included as an inorganic filler in the molding material 140, it may be absorbed into the molding material 140 during a subsequent molding process without performing a separate removal process.

Due to structural limitations arising because the size of the buffer die 110 along the horizontal direction is larger than the size of the memory die 120 and 120T along the horizontal direction, it may be difficult to remove the fillet generated from the underfill member 132 between the buffer die 110 and the memory die 120 corresponding to the lowermost portion using mechanical cutting equipment. However, according to the present inventive concept, the fillet generated from the underfill member 132 between the buffer die 110 and the memory die 120 may also be easily removed by performing an oxygen plasma etching process.

In addition, according to the present inventive concept, fillets formed in the semiconductor stacks S disposed on the wafer 110W may be removed at once by performing plasma etching, reducing the time required to remove the fillets and increasing productivity of the high bandwidth memory (HBM) 100.

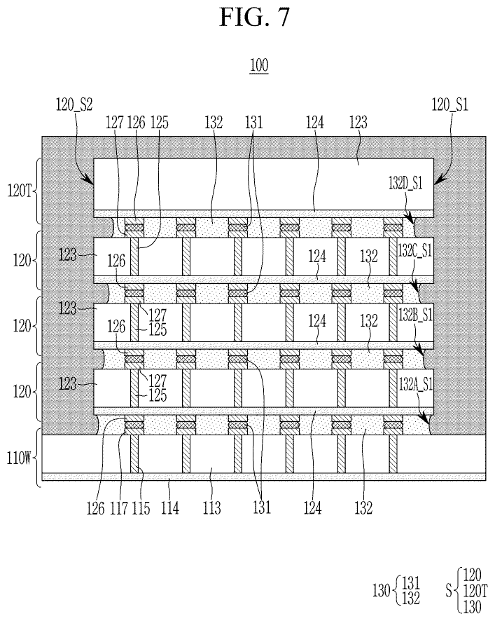

FIG. 7 is a cross-sectional view illustrating a step of molding the semiconductor stacks S on the semiconductor wafer 110W.

Referring to FIG. 7, the memory dies 120 and the underfill members 132 may be molded with a molding material 140 on the semiconductor wafer 110W. During the molding process, a molding material 140 may be filled in the etched portion between the wafer 110W and the memory die 120 adjacent to the wafer 110W, or between the neighboring memory dies 120 and 120T among the memory dies 120 and 120T. The molding material 140 may contact the recessed sides 132A_S1, 132B_S1, 132C_S1, and 132D_S1 of each of the underfill members 132. The process of molding with the molding material 140 may include compression molding or transfer molding process.

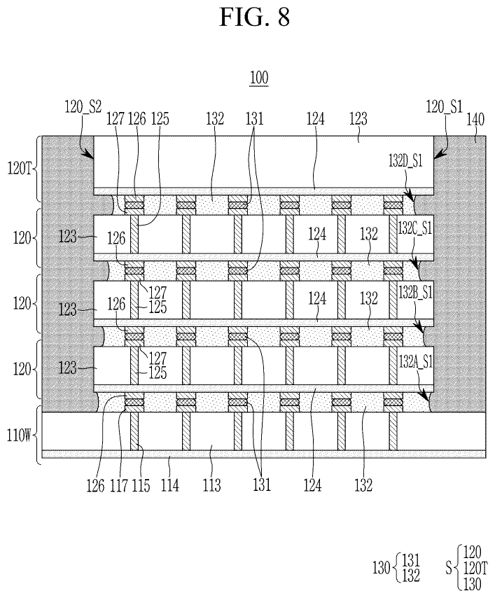

FIG. 8 is a cross-sectional view illustrating a step of performing a chemical mechanical planarization (CMP) process on a molding material 140.

Referring to FIG. 8, a chemical mechanical planarization (CMP) process may be performed to planarize the upper surface of the molding material 140. After performing a chemical mechanical planarization (CMP) process, the upper surface of the memory die 120T may be exposed.

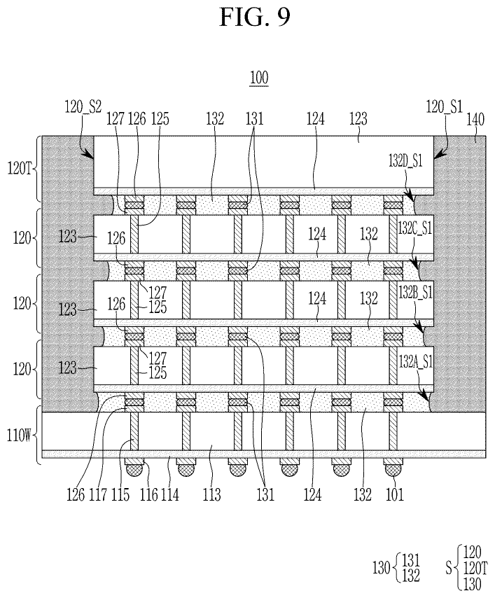

FIG. 9 is a cross-sectional view illustrating the step of forming the external connection members 101 on a bottom surface of the wafer 110W.

Referring to FIG. 9, external connection members 101 may be formed on the bottom surface of the wafer 110W. The external connection member 101 may include at least one of tin, silver, lead, nickel, copper, and alloys thereof. Thereafter, the reconfigured wafer 110W may be individualized into high bandwidth memories (HBMs).

Although the preferred embodiment of the present disclosure has been described above, the present disclosure is not necessarily limited thereto, and it is possible to perform various modifications within the scope of the claims, the detailed description of the disclosure, and the accompanying drawings, and it is natural to fall within the scope of the present disclosure.

What is claimed is:

1. A high bandwidth memory comprising:
a base die; and
a semiconductor stack disposed on the base die, the semiconductor stack comprising a plurality of underfill members and a plurality of memory dies that are alternately stacked,
wherein each of the plurality of underfill members includes first sides,
wherein each of the plurality of memory dies includes second sides, and
wherein each of the first sides is recessed from a corresponding second side.

2. The high bandwidth memory of claim 1, wherein
the plurality of underfill members comprise a non-conductive film.

3. The high bandwidth memory of claim 1, wherein
the plurality of underfill members comprise at least one of a thermosetting resin, a hardener, a catalyst, a flux, a thermoplastic resin, and an inorganic filler.

4. The high bandwidth memory of claim 1, wherein
each of the first sides of the plurality of underfill members is more recessed from a corresponding second side as the plurality of underfill members is farther away from the base die.

5. The high bandwidth memory of claim 1, wherein
each of the first sides of the plurality of underfill members comprises a concave profile.

6. A high bandwidth memory comprising:
a buffer die;
a semiconductor stack disposed on the buffer die; and
a molding material covering the semiconductor stack disposed on the buffer die,
wherein the semiconductor stack comprises,
a plurality of core dies stacked in vertical direction; and
a plurality of interconnection structures, each interconnection structure being disposed between the buffer die and a core die adjacent to the buffer die, or between neighboring core dies,
wherein each of the plurality of interconnection structures comprises:
a plurality of connection members; and
an underfill member disposed around the plurality of connection members,
wherein the underfill member between neighboring core dies comprises first sides,
wherein each of the plurality of core dies comprises second sides, and
wherein each of the first sides of the underfill member is recessed from a corresponding second side.

7. The high bandwidth memory of claim 6, wherein
the first sides of the underfill member are in contact with the molding material.

8. The high bandwidth memory of claim 6, wherein
the underfill member between the buffer die and the core die adjacent to the buffer die includes third sides,
each of the third sides being recessed from a corresponding second side of the plurality of core dies.

9. The high bandwidth memory of claim 8, wherein
the third sides are in contact with the molding material.

10. The high bandwidth memory of claim 6, wherein
the molding material comprises an epoxy molding compound.

11. The high bandwidth memory of claim 6, wherein
the molding material comprises at least one of a thermosetting resin, a hardener, a flame retardant, a catalyst, a release agent, a modifier, a colorant, and an inorganic filler.

12. The high bandwidth memory of claim 6, wherein
the molding material covers a predetermined distance from each of the first sides of the underfill member to a corresponding second side of the plurality of core dies.

13. The high bandwidth memory of claim 12, wherein
the predetermined distance increases as the distance of the underfill member from the buffer die increases.

14. A method of manufacturing a high bandwidth memory comprising:
stacking a plurality of underfill members and a plurality of memory dies alternately on a base die;
performing plasma etching such that each of first sides of the plurality of underfill members is recessed from a corresponding second side of the plurality of memory dies; and
molding the plurality of underfill members and the plurality of memory dies with a molding material on the base die.

15. The method of manufacturing a high bandwidth memory of claim 14, wherein
the plasma etching comprises oxygen plasma etching.

16. The method of manufacturing a high bandwidth memory of claim 14, wherein
the plasma etching comprises isotropic plasma etching.

17. The method of manufacturing a high bandwidth memory of claim 14, wherein
the plurality of underfill members comprise silica.

18. The method of manufacturing a high bandwidth memory of claim 17, wherein
after performing the plasma etching, the silica remains as an etching by-product for the plurality of underfill members, and
the silica is not removed.

19. The method of manufacturing a high bandwidth memory of claim 17,
further comprising removing the silica by flushing prior to the molding,
wherein after performing the plasma etching, the silica remains as an etching by-product of the plurality of underfill members.

20. The method of manufacturing a high bandwidth memory of claim 14, wherein:
the plasma etching is performed at a temperature ranging from about 70° C. to about 250° C.
